(19) United States
(12) Patent Application Publication
(10) Pub. No.: US 2012/0056272 A1
(43) Pub. Date: Mar. 8, 2012

(54) SEMICONDUCTOR DEVICE

(75) Inventor: Junji HIRASE, Toyama (JP)

(73) Assignee: Panasonic Corporation, Osaka (JP)

(21) Appl. No.: 13/297,741

(22) Filed: Nov. 16, 2011

Related U.S. Application Data
(63) Continuation of application No. PCT/JP2010/000294, filed on Jan. 20, 2010.

(30) Foreign Application Priority Data
Jun. 17, 2009 (JP) 2009-144106

(51) Int. Cl. H01L 27/088

(52) U.S. Cl. 257/392; 257/E27.06

(57) ABSTRACT

A semiconductor device includes a first transistor having a first conductivity type; and a second transistor having the first conductivity type and having a higher threshold voltage than the first transistor. The first transistor includes a first channel region having a second conductivity type, a first gate insulating film, a first gate electrode, and a first extension region having the first conductivity type. The second transistor includes a second channel region having the second conductivity type, a second gate insulating film, a second gate electrode, and a second extension region having the first conductivity type. The second extension region contains impurities for shallower junction. A junction depth of the second extension region is shallower than a junction depth of the first extension region.

### CROSS-REFERENCE TO RELATED APPLICATION

This is a continuation of PCT International Application PCT/JP2010/000294 filed on Jan. 20, 2010, which claims priority to Japanese Patent Application No. 2009-144106 filed on Jun. 17, 2009. The disclosures of these applications including the specifications, the drawings, and the claims are hereby incorporated by reference in their entirety.

### BACKGROUND

The present disclosure relates to semiconductor devices and manufacturing methods of the devices, and more particularly to semiconductor devices including two metal insulator semiconductor field effect transistors (MISFETs) having different threshold voltages and manufacturing methods of the devices.

In recent years, a Multi-Vt technique is generally used to achieve both of an increase in performance and reduction in power consumption of semiconductor integrated circuit devices. (See, for example, Japanese Patent Publication No. 2004-14779.) The Multi-Vt technique is a technique of mounting MISFETs (hereinafter referred to as “MIS transistors”) having a same conductivity type and different threshold voltages on a same semiconductor substrate.

A manufacturing method of a conventional semiconductor device using the Multi-Vt technique will be described below with reference to FIGS. 5A-5D. FIGS. 5A-5D are cross-sectional views illustrating the manufacturing method of the conventional semiconductor device in order of steps. In FIGS. 5A-5D, a reference character “Lvt” denotes a formation region of a first n-type MIS transistor, on which the first n-type MIS transistor having a relatively low threshold voltage is formed. A reference character “Hvt” denotes a formation region of a second n-type MIS transistor, on which the second n-type MIS transistor having a relatively high threshold voltage is formed.

First, in the step shown in FIG. 5A, an isolation region 102 is formed in the upper portion of a silicon substrate 101. As a result, a first active region 101a surrounded by the isolation region 102 and formed of the silicon substrate 101 is provided in the formation region Lvt of the first n-type MIS transistor. A second active region 101b surrounded by the isolation region 102 and formed of the silicon substrate 101 is provided in the formation region Hvt of the second n-type MIS transistor.

Then, p-type impurities are implanted into an upper portion of the first active region 101a to form a first p-type channel region 103a, while p-type impurities are implanted into an upper portion of the second active region 101b to form a second p-type channel region 103b. At this time, the p-type impurities are implanted into the upper portion of the first active region 101a and the upper portion of the second active region 101b so that the concentration of the p-type impurities in the second p-type channel region 103b is higher than the concentration of the p-type impurities in the first p-type channel region 103a.

Next, a gate insulating film 104 and a polysilicon film 105 are sequentially formed on an upper surface of the silicon substrate 101.

After that, in the step shown in FIG. 5B, the gate insulating film 104 and the polysilicon film 105 are patterned. As a result, a first gate insulating film 104a and a first gate electrode 105a are sequentially formed on the first p-type channel region 103a, and a second gate insulating film 104b and a second gate electrode 105b are sequentially formed on the second p-type channel region 103b.

Then, a first n-type extension region 106a and a first p-type pocket region (not shown) are formed in a portion of the first active region 101a, which is located below a side of the first gate electrode 105a. A second n-type extension region 106b and a second p-type pocket region (not shown) are formed in a portion of the second active region 101b, which is located below a side of the second gate electrode 105b.

Next, in the step shown in FIG. 5C, first sidewalls 107a are formed on side surfaces of the first gate electrode 105a, and second sidewalls 107b are formed on side surfaces of the second gate electrode 105b.

After that, first n-type source/drain regions 108a are formed in portions of the first active region 101a, which are located below sides of the first sidewalls 107a. Second n-type source/drain regions 108b are formed in portions of the second active region 101b, which are located below sides of the second sidewalls 107b. Then, the silicon substrate 101 is subjected to heat treatment to activate conductive impurities. Next, silicide films 109 are formed in upper portions of the first gate electrode 105a, the second gate electrode 105b, the first n-type source/drain regions 108a, and the second n-type source/drain regions 108b. As a result, the conventional semiconductor device using the Multi-Vt technique is manufactured. As such, when the concentration of the p-type impurities in the second p-type channel region 103b is higher than the concentration of the p-type impurities in the first p-type channel region 103a, the threshold voltage of the second MIS transistor can be higher than the threshold voltage of the first MIS transistor.

### SUMMARY

However, when the impurity concentration in the second channel region is higher than the impurity concentration in the first channel region, and such a semiconductor device is operated, the conductive impurities tend to collide with carriers in the second channel region as compared to the first channel region. Thus, since the carriers tend to be scattered in the second channel region as compared to the first channel region, carrier mobility may decrease in the second MIS transistor as compared to the first MIS transistor.

The present disclosure was made in view of the problems. It is an objective of the present disclosure to mitigate reduction in driving force of a transistor having a relatively high threshold voltage in a semiconductor device including transistors having different threshold voltages and a manufacturing method of the device.

A semiconductor device according to the present disclosure includes a first transistor having a first conductivity type; and a second transistor having the first conductivity type and having a higher threshold voltage than the first transistor. The first transistor includes a first channel region having a second conductivity type, a first gate insulating film, a first gate electrode, and a first extension region having the first conductivity type. The first channel region is formed in a first active region of a semiconductor substrate. The first gate insulating film is provided on the first channel region of the first active region. The first gate electrode is provided on the first gate insulating film. The first extension region is formed in a part of the first active region which is located below a side of the first gate electrode. The second transistor includes a second channel region having the second conductivity type, a second gate insulating film, a second gate electrode, and a second extension region having the first conductivity type. The second channel region is formed in a second active region of the semiconductor substrate. The second gate insulating film is provided on the second channel region of the second active region. The second gate electrode is provided on the second gate insulating film. The second extension region is formed in a part of the second active region which is located below a side of the second gate electrode. The second extension region contains impurities for shallower junction. A junction depth of the second extension region is shallower than a junction depth of the first extension region.

In a semiconductor device having the above structure, since the junction depth of the second extension region is shallower than the junction depth of the first extension region, the effective channel length of the second transistor is greater than the effective channel length of the first transistor. Thus, a short channel effect can be reduced in the second transistor, as compared to the first transistor. This makes the threshold voltage of the second transistor higher than the threshold voltage of the first transistor.

The first extension region may not contain the impurities for shallower junction, and may contain the impurities for shallower junction. When the first extension region contains the impurities for shallower junction, a concentration of the impurities for shallower junction in the first extension region is preferably lower than a concentration of the impurities for shallower junction in the second extension region. In each of the cases, the junction depth of the second extension region is shallower than the junction depth of the first extension region. Therefore, the short channel effect can be reduced in the second transistor, as compared to the first transistor.

The impurities for shallower junction preferably have no conductivity. The impurities for shallower junction may be at least one of C, N, F, Ar, or Ge. Alternately, when the semiconductor substrate is made of silicon, a silicon concentration in a region implanted with the impurities for shallower junction may be higher than a silicon concentration in the semiconductor substrate except for the region implanted with the impurities. Regardless of which of the above specific examples is selected as the impurities for shallower junction, the junction depth of the second extension region is shallower than the junction depth of the first extension region.

A junction depth of a region implanted with the impurities for shallower junction may be deeper than a junction depth of the second extension region, and may be shallower than the junction depth of the second extension region.

In the former case, diffusion of the conductive impurities forming the second extension region can be reduced. In the latter case, the implant depth of the conductive impurities forming the second extension region can be shallow.

The first channel region preferably has an impurity concentration substantially equal to an impurity concentration of the second channel region. This mitigates reduction in carrier mobility in the second channel region.

In a manufacturing method of a semiconductor device according to the present disclosure, the semiconductor device is manufactured, which includes a first transistor having a first conductivity type and formed on the first active region of the semiconductor substrate; and a second transistor having the first conductivity type, formed on the second active region of the semiconductor substrate, and having a higher threshold voltage than the first transistor. Specifically, the method includes the steps of (a) forming a first channel region having the second conductivity type in the first active region, while forming a second channel region having the second conductivity type in the second active region; (b) after the step (a), forming a first gate electrode on the first channel region of the first active region with a first gate insulating film interposed therebetween, while forming a second gate electrode on the second channel region of the second active region with a second gate insulating film interposed therebetween; (c) after the step (b), selectively ion-implanting impurities for shallower junction into a part of the second active region below a side of the second gate electrode to form a region implanted with the impurities for shallower junction; (d) after the step (b), ion-implanting impurities having the first conductivity type into a part of the first active region below a side of the first gate electrode to from a first extension implant region, while ion-implanting impurities having the first conductivity type into a part of the second active region below a side of the second gate electrode to form a second extension implant region; and (e) after the steps (c) and (d), performing heat treatment to the semiconductor substrate to form a first extension region in a part of the first active region below a side of the first gate electrode, while forming a second extension region in a part of the second active region below a side of the second gate electrode.

In the step (c), “selectively ion-implanting impurities for shallower junction” means, for example, ion-implanting impurities for shallower junction into a predetermined position using a resist mask etc.

In such a manufacturing method of the semiconductor device, a junction depth of the second extension region can be shallower than a junction depth of the first extension region. Thus, a short channel effect can be reduced in the second transistor, as compared to the first transistor. Therefore, the threshold voltage of the second transistor can be higher than the threshold voltage of the first transistor.

The step (c) may be performed before the step (e), and may be performed before the step (d). In the former case, diffusion of the conductive impurities existing in the second extension implant region can be reduced. In this case, the implant depth of the second extension implant region is preferably shallower than the implant depth of a region implanted with the impurities for shallower junction. In the latter case, the implant depth of the second extension implant region can be shallower than the implant depth of the first extension implant region.

As described above, according to the present disclosure, reduction in driving force of a transistor having a relatively high threshold voltage can be mitigated.

### BRIEF DESCRIPTION OF THE DRAWINGS

FIGS. 1A-1E are cross-sectional views illustrating a manufacturing method of a semiconductor device according to a first embodiment of the present disclosure in order of steps.

FIG. 2 is a cross-sectional view illustrating the semiconductor device according to the first embodiment.

FIGS. 3A-3C are cross-sectional views illustrating a manufacturing method of a semiconductor device according to a second embodiment of the present disclosure in order of steps.

FIG. 4 is a cross-sectional view illustrating the semiconductor device according to the second embodiment.

FIGS. 5A-5D are cross-sectional views illustrating a manufacturing method of a conventional semiconductor device in order of steps.

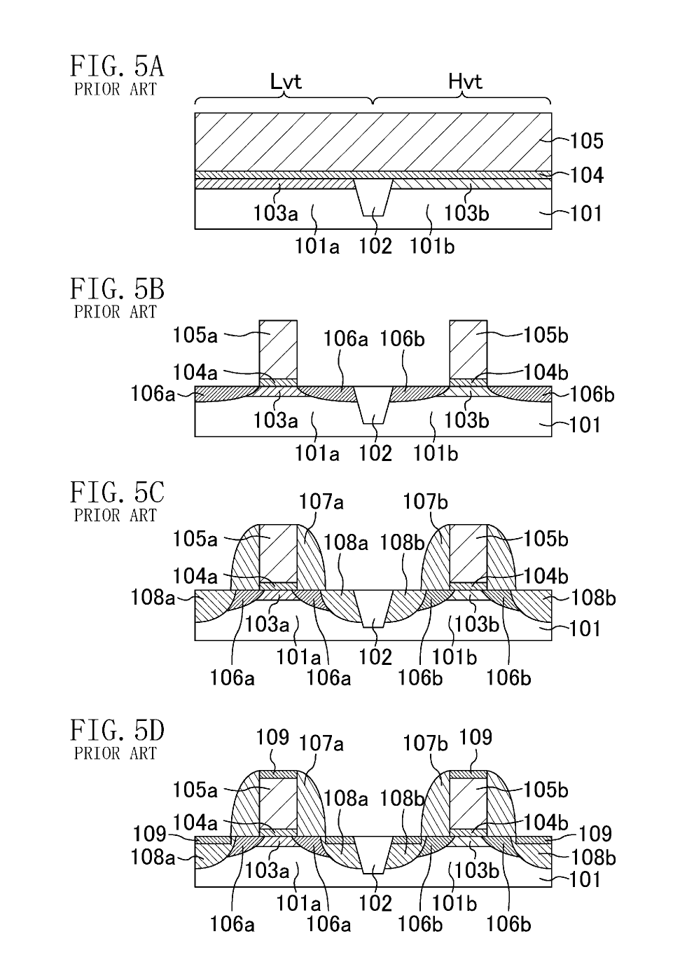

### DETAILED DESCRIPTION

Embodiments of the present disclosure will be described hereinafter in detail with reference to the drawings. Note that the present disclosure is not limited to the embodiments described below. Specifically, materials of films, thicknesses of the films, formation methods of the films, conditions of film formation, conditions of ion implantation, etc. are not limited to the specific examples shown in the following embodiments. The same reference characters are used to represent equivalent elements, and the explanation thereof may be omitted.

### First Embodiment

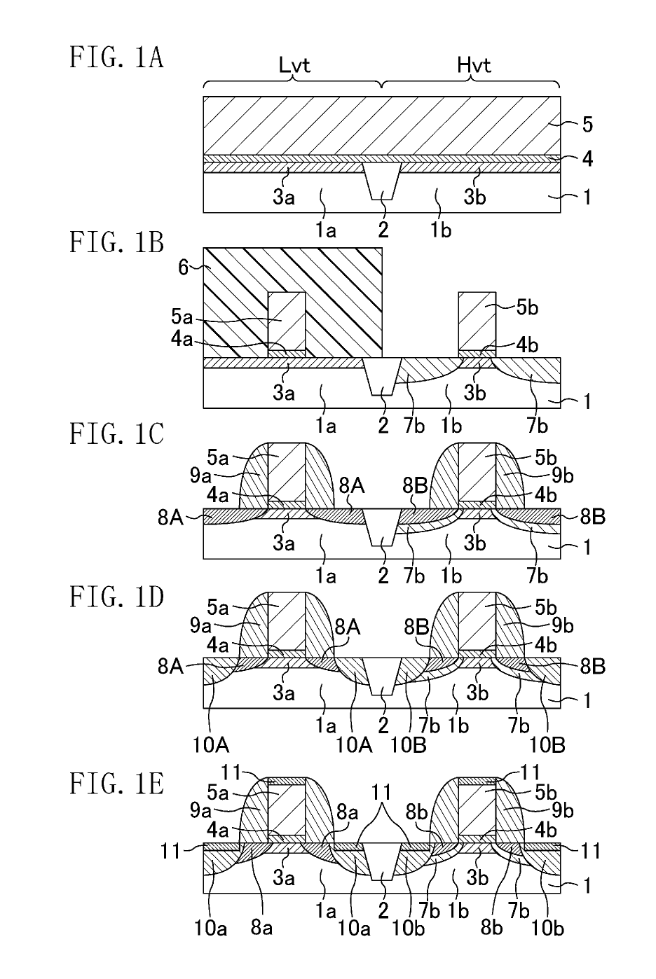

A manufacturing method of a semiconductor device according to a first embodiment of the present disclosure will be described below with reference to FIGS. 1A-1E.

FIGS. 1A-1E are cross-sectional views illustrating the manufacturing method of the semiconductor device according to this embodiment in order of steps. In the drawings, a reference character “Lvt” on the left side denotes a formation region Lvt of a first n-type MIS transistor, on which the first n-type MIS transistor having a relatively low threshold voltage is formed. A reference character “Hvt” on the right side denotes a formation region Hvt of a second n-type MIS transistor, on which the second n-type MIS transistor having a relatively high threshold voltage is formed.

First, in the step shown in FIG. 1A, an isolation region 2, which is formed by filling an insulating film in a trench, is selectively formed by, for example, shallow trench isolation (STI) in an upper portion of a substrate (hereinafter referred to as a “semiconductor substrate”) 1 having a first conductivity type and including a semiconductor region such as a silicon region. As a result, a first active region 1a surrounded by the isolation region 2 and formed of the semiconductor substrate 1 is provided in the formation region Lvt of the first n-type MIS transistor. A second active region 1b surrounded by the isolation region 2 and formed of the semiconductor substrate 1 is provided in the formation region Hvt of the second n-type MIS transistor.

Then, although it is not shown in the figure, p-type impurities such as boron are ion-implanted into the first active region 1a to form a p-type well region and a p-type punch-through stopper in the first active region 1a. Also, p-type impurities such as boron are ion-implanted into the second active region 1b to form a p-type well region and a p-type punch-through stopper in the second active region 1b. As the implantation conditions for forming the p-type well regions, the implant energy may be, for example, 200 keV, and the implant dose may be, for example, 1×10¹³ cm⁻². As the implantation conditions for forming the p-type punch-through stoppers, the implant energy may be, for example, 100 keV, and the implant dose may be, for example, 1×10¹³ cm⁻².

Next, p-type impurities such as boron are ion-implanted into an upper portion of the first active region 1a to form a first p-type channel region 3a in the upper portion of the first active region 1a (step (a)). Also, p-type impurities such as boron are ion-implanted into an upper portion of the second active region 1b to form a second p-type channel region 3b in the upper portion of the second active region 1b (step (a)). As the implantation conditions, the implant energy may be, for example, 30 keV, and the implant dose may be, for example, 2×10¹² cm⁻². The implant dose of the p-type impurities into the upper portion of the first active region 1a is equal to the implant dose of the p-type impurities into the upper portion of the second active region 1b. Thus, the concentration of the p-type impurities in the first p-type channel region 3a is equal to the concentration of the p-type impurities in the second p-type channel region 3b. This mitigates reduction in carrier mobility in the second p-type channel region 3b.

Then, after forming a gate insulating film 4 on an upper surface of the semiconductor substrate 1, for example, a polysilicon film 5 is formed on an upper surface of the gate insulating film 4. The gate insulating film 4 has a thickness of, for example, 2 nm, and is, for example, a silicon oxide film. The polysilicon film 5 has a thickness of, for example, 100 nm.

Next, in the step shown in FIG. 1B, a resist pattern (not shown) in the form of a gate pattern is provided on an upper surface of the polysilicon film 5. After that, the gate insulating film 4 and the polysilicon film 5 are dry-etched using the resist pattern as a mask. As a result, a first gate insulating film 4a and a first gate electrode 5a are sequentially formed on the first p-type channel region 3a, and a second gate insulating film 4b and a second gate electrode 5b are sequentially formed on the second p-type channel region 3b (step (b)). Each of the first gate insulating film 4a and the second gate insulating film 4b is the patterned gate insulating film 4. Each of the first gate electrode 5a and the second gate electrode 5b is the patterned polysilicon film 5.

Then, an upper surface of the first active region 1a and an upper surface of a portion of the isolation region 2 around the first active region 1a are covered with a resist mask 6. Impurities for shallower junction are implanted using the resist mask 6 and the second gate electrode 5b as a mask. As a result, an implant region 7b of impurities for shallower junction is formed in the second active region 1b below a side of the second gate electrode 5b (step (c)). After that, the resist mask 6 is removed.

The impurities for shallower junction preferably have no conductivity type, and may be, for example, at least one of C, N, F, Ar, Ge, or Si. In this embodiment, the impurities for shallower junction are preferably at least one of C, N, or F. When C is used as the impurities for shallower junction, the implant energy may be, for example, 10 keV, and the implant dose may be, for example, 1×10¹⁵ cm⁻². The impurities for shallower junction will be described later.

Then, in the step shown in FIG. 1C, n-type impurities such as arsenic are implanted into the first active region 1a using the first gate electrode 5a as a mask, while n-type impurities such as arsenic are implanted into the second active region 1b using the second gate electrode 5b as a mask. As the implantation conditions, the implant energy may be, for example, 2 keV, and the implant dose may be, for example, 1×10¹⁵ cm⁻². As a result, a first n-type extension implant region 8A is formed in the first active region 1a below a side of the first gate electrode 5a (step (d)). Also, a second n-type extension implant region 8B is formed in the second active region 1b below the side of the second gate electrode 5b at a higher position than the implant region 7b of the impurities for shallower junction (step (d)). That is, the implant depth of the second n-type extension implant region 8B is shallower than the implant depth of the implant region 7b of the impurities for shallower junction. The second n-type extension implant region 8B contains not only the n-type impurities but also the impurities for shallower junction.

Next, p-type impurities such as boron are ion-implanted into the first active region 1a using the first gate electrode 5a as a mask, while p-type impurities such as boron are implanted into the second active region 1b using the second gate electrode 5b as a mask. As the implantation conditions, the implant energy may be, for example, 10 keV, and the implant dose may be, for example, 1×10¹³ cm⁻². As a result, a first p-type pocket implant region (not shown) is formed in the first active region 1a below the side of the first gate electrode 5a and at a lower position than the first n-type extension implant region 8A. A second p-type pocket implant region (not shown) is formed in the second active region 1b below the side of the second gate electrode 5b and at a lower position than the second n-type extension implant region 8B.

After that, an insulating film (not shown) is formed on the entire upper surface of the semiconductor substrate 1 by, for example, chemical vapor deposition (CVD). The insulating film has a thickness of, for example, 50 nm, and is, for example, a silicon oxide film. Then, the insulating film is subject to anisotropic etching. As a result, first sidewalls 9a are formed on side surfaces of the first gate electrode 5a, and second sidewalls 9b are formed on side surfaces of the second gate electrode 5b.

Then, in the step shown in FIG. 1D, n-type impurities such as arsenic are ion-implanted into the first active region 1a using the first gate electrode 5a and the first sidewalls 9a as a mask, while n-type impurities such as arsenic are ion-implanted into the second active region 1b using the second gate electrode 5b and the second sidewalls 9b as a mask. As the implantation conditions, the implant energy may be, for example, 10 keV, and the implant dose may be, for example, 5×10¹⁵ cm⁻². As a result, first n-type source/drain implant regions 10A are formed in the first active region 1a below sides of the first sidewalls 9a, and second n-type source/drain implant regions 10B are formed in the second active region 1b below sides of the second sidewalls 9b.

Next, in the step shown in FIG. 1E, the semiconductor substrate 1 is subject to spike rapid thermal annealing (RTA) at a temperature of, for example, 1050° C. (step (e)). This heat treatment electrically activates and diffuses the n-type impurities existing in the first and second n-type extension implant regions 8A and 8B to a predetermined position. As a result, a first n-type extension region 8a is formed in the first active region 1a below the side of the first gate electrode 5a, and a second n-type extension region 8b is formed in the second active region 1b below the side of the second gate electrode 5b and at a higher position than the implant region 7b of the impurities for shallower junction. Similarly, this heat treatment electrically activates and diffuses the p-type impurities existing in the first and second p-type pocket implant regions to a predetermined position. As a result, a first p-type pocket region (not shown) is formed in the first active region 1a below the side of the first gate electrode 5a and at a lower position than the first n-type extension region 8a. A second p-type pocket region (not shown) is formed in the second active region 1b below the side of the second gate electrode 5b and at a lower position than the second n-type extension region 8b. Furthermore, this heat treatment electrically activates and diffuses the n-type impurities existing in the first and second n-type source/drain implant regions 10A and 10B to a predetermined position. As a result, first n-type source/drain regions 10a are formed in the first active region 1a below the sides of the first sidewalls 9a, and second n-type source/drain regions 10b are formed in the second active region 1b below the sides of the second sidewalls 9b.

At this time, the implant region 7b of the impurities for shallower junction is formed under the second n-type extension implant region 8B in the second active region 1b. In this embodiment, the impurities for shallower junction reduce diffusion of the n-type impurities existing in the second n-type extension implant region 8B during the spike RTA (the step of diffusing the conductive impurities). As a result, as shown in FIG. 1E, the junction depth of the second n-type extension region 8b is shallower than the junction depth of the first n-type extension region 8a. For example, when the junction depth of the first n-type extension region 8a is 15 nm, the junction depth of the second n-type extension region 8b is about 10 nm. When the junction depth of the first n-type extension region 8a is 20 nm, the junction depth of the second n-type extension region 8b is about 15 nm. As such, the impurities for shallower junction reduces diffusion of the n-type impurities due to the heat treatment, and makes the junction depth of the second n-type extension region 8b shallower than the junction depth of the first n-type extension region 8a.

When at least one of C, N, or F is selected as the impurities for shallower junction, the impurities for shallower junction can be implanted into a relatively deep position in the second active region 1b. Thus, since the implant region 7b of the impurities for shallower junction can be formed at a lower position than the second n-type extension implant region 8B, the diffusion of the n-type impurities existing in the second n-type extension implant region 8B can be effectively reduced during the spike RTA. Therefore, in this embodiment, at least one of C, N, or F is preferably selected as the impurities for shallower junction.

Since the second n-type extension implant region 8B contains not only the n-type impurities, but also the impurities for shallower junction, the second n-type extension region 8b contains not only the n-type impurities, but also the impurities for shallower junction.

After that, a metal film for silicidation (not shown) is deposited on the entire upper surface of the semiconductor substrate 1 by sputtering. The metal film for silicidation may be a nickel film with a thickness of 10 nm. Then, the semiconductor substrate 1 is subject to first RTA in, for example, a nitrogen atmosphere and at a temperature of 320° C. As a result, silicon in the first and second n-type source/drain regions 10a and 10b reacts to metal (nickel in this embodiment) in the metal film for silicidation, and silicon in the first and second gate electrodes 5a and 5b reacts to metal in the metal film for silicidation. Then, the semiconductor substrate 1 is immersed into an etchant made of a mixture of sulfuric acid and hydrogen peroxide. This removes an unreacted metal film for silicidation (which remains on the isolation region 2, the first sidewalls 9a, the second sidewalls 9b, etc.). After that, the semiconductor substrate 1 is subject to second RTA at a higher temperature (e.g., 550° C.) than the temperature of the first RTA. As a result, silicide films (nickel silicide films in this embodiment) 11 are formed in upper portions of the first and second n-type source/drain regions 10a and 10b, and in upper portions of the first and second gate electrodes 5a and 5b. As a result, the semiconductor device according to this embodiment can be manufactured.

In the manufacturing method of the semiconductor device according to this embodiment, the implant region 7b of the impurities for shallower junction is formed in the second active region 1b in the step shown in FIG. 1B. Thus, when the conductive impurities are diffused in the step shown in FIG. 1E, the n-type impurities existing in the second n-type extension implant region 8B are less likely to be diffused than the n-type impurities existing in the first n-type extension implant region 8A. Therefore, as shown in FIG. 1E, the junction depth of the second n-type extension region 8b becomes shallower than the junction depth of the first n-type extension region 8a. In the manufactured semiconductor device, an effective channel length of the second n-type MIS transistor is greater than an effective channel length of the first n-type MIS transistor. As a result, since a short channel effect can be reduced in the second n-type MIS transistor as compared to the first n-type MIS transistor, the threshold voltage of the second n-type MIS transistor can be higher than the threshold voltage of the first n-type MIS transistor. For example, when the threshold voltage of the first n-type MIS transistor is 0.2 V, the threshold voltage of the second n-type MIS transistor can be 0.3 V.

In the manufacturing method of the semiconductor device according to this embodiment, the threshold voltage of the second n-type MIS transistor can be higher than the threshold voltage of the first n-type MIS transistor without making the concentration of the p-type impurities in the second p-type channel region 3b higher than the concentration of the p-type impurities in the first p-type channel region 3a. Therefore, in the manufactured semiconductor device, the collision between the p-type impurities and carriers in the second p-type channel region 3b can be reduced, thereby mitigating reduction in the carrier mobility in the second p-type channel region 3b. That is, in the manufacturing method of the semiconductor device according to this embodiment, the threshold voltage of the second n-type MIS transistor can be higher than the threshold voltage of the first n-type MIS transistor without reducing driving force of the second n-type MIS transistor.

Three methods have been known as a method of increasing a threshold voltage. The first method is to increase the concentration of conductive impurities in a channel region. The second method is to increase the concentration of conductive impurities in a pocket region. The third method is to reduce the concentration of conductive impurities in source/drain regions. In the first method, as described above, the conductive impurities tend to collide with carriers in the channel region, thereby reducing carrier mobility in the channel region. In the second method, the conductive impurities tend to be diffused from the pocket region to the channel region, the conductive impurities tend to collide with the carriers in the channel region. This reduces the carrier mobility in the channel region as in the first method. In the third method, resistances of the source/drain regions increase to reduce driving force due to parasitic resistance. However, in the manufacturing method of the semiconductor device according to this embodiment, the threshold voltage of the second n-type MIS transistor can be higher than the threshold voltage of the first n-type MIS transistor without making the concentration of the p-type impurities in the second p-type channel region 3b higher than the concentration of the p-type impurities in the first p-type channel region 3a, without making the concentration of the p-type impurities in the second p-type pocket region higher than the concentration of the p-type impurities in the first p-type pocket region, or without making the concentration of the n-type impurities in the second n-type source/drain regions 10b lower than the concentration of the n-type impurities in the first n-type source/drain regions 10a. Therefore, in the manufacturing method of the semiconductor device according to this embodiment, the threshold voltage of the second n-type MIS transistor can be higher than the threshold voltage of the first n-type MIS transistor, without reducing the carrier mobility in the second p-type channel region 3b, or without reducing the driving force of the second n-type MIS transistor due to parasitic resistance.

Furthermore, in the step shown in FIG. 1C, a second p-type pocket implant region (not shown) is formed below the second n-type extension implant region 8B. Thus, when the conductive impurities are diffused in the step shown in FIG. 1E, the p-type impurities existing in the second p-type pocket implant region may be less likely to be diffused than the p-type impurities existing in the first p-type pocket implant region. This reduces diffusion of the p-type impurities from the second p-type pocket region to the second p-type channel region 3b, thereby preventing an increase in the concentration of the p-type impurities in the second p-type channel region 3b. Therefore, reduction in the carrier mobility in the second p-type channel region 3b can be mitigated.

In addition, in the step shown in FIG. 1D, the second n-type source/drain implant regions 10B are formed in the second active region 1b below the sides of the second sidewalls 9b. Thus, when the conductive impurities are diffused in the step shown in FIG. 1E, the n-type impurities existing in the second n-type source/drain implant regions 10B may be less likely to be diffused than the n-type impurities existing in the first n-type source/drain implant regions 10A. Thus, the junction depths of the second n-type source/drain regions 10b can be shallower than the junction depths of the first n-type source/drain regions 10a. This also allows the threshold voltage of the second n-type MIS transistor to be higher than the threshold voltage of the first n-type MIS transistor.

In order to make the junction depths of the second n-type source/drain regions 10b shallower than the junction depths of the first n-type source/drain regions 10a, the implant region 7b of the impurities for shallower junction is preferably formed below each side of the second sidewalls 9b and at a lower position than the second n-type source/drain implant regions 10B.

In this embodiment, only the implant region 7b of the impurities for shallower junction is formed in the step shown in FIG. 1B. However, with the first active region 1a covered with the resist mask 6, n-type impurities which are part of the second n-type extension implant region, p-type impurities which are part of the second p-type pocket implant region, or both of n-type impurities (n-type impurities which are part of the second n-type extension implant region) and p-type impurities (p-type impurities which are part of the second p-type pocket implant region) may be implanted into the second active region 1b before or after forming the implant region 7b of the impurities for shallower junction. Then, in the step shown in FIG. 1C, n-type impurities are implanted into the first active region 1a to form the first n-type extension implant region 8A, while n-type impurities are implanted into the second active region 1b to form the second n-type extension implant region 8B. At this time, the dose of the n-type impurities in the second n-type extension implant region 8B is the sum of the dose of the n-type impurities implanted into the second active region 1b in the step shown in FIG. 1C and the dose of the n-type impurities implanted into the second active region 1b in the step shown in FIG. 1B. As a result, the dose of the n-type impurities in the second n-type extension implant region 8B can be larger than the dose of the n-type impurities in the first n-type extension implant region 8A.

Similarly, in the step shown in FIG. 1C, the p-type impurities are implanted into the first active region 1a to form the first p-type pocket implant region, while the p-type impurities are implanted into the second active region 1b to form the second p-type pocket implant region. At this time, the dose of the p-type impurities in the second p-type pocket implant region is the sum of the dose of the p-type impurities implanted into the second active region 1b in the step shown in FIG. 1C and the dose of the p-type impurities implanted into the second active region 1b in the step shown in FIG. 1B. As a result, the dose of the p-type impurities in the second p-type pocket implant region can be larger than the dose of the p-type impurities in the first p-type pocket implant region.

As described above, in the manufacturing method of the semiconductor device according to this embodiment, the threshold voltage of the second n-type MIS transistor can be higher than the threshold voltage of the first n-type MIS transistor without reducing the driving force of the second n-type MIS transistor.

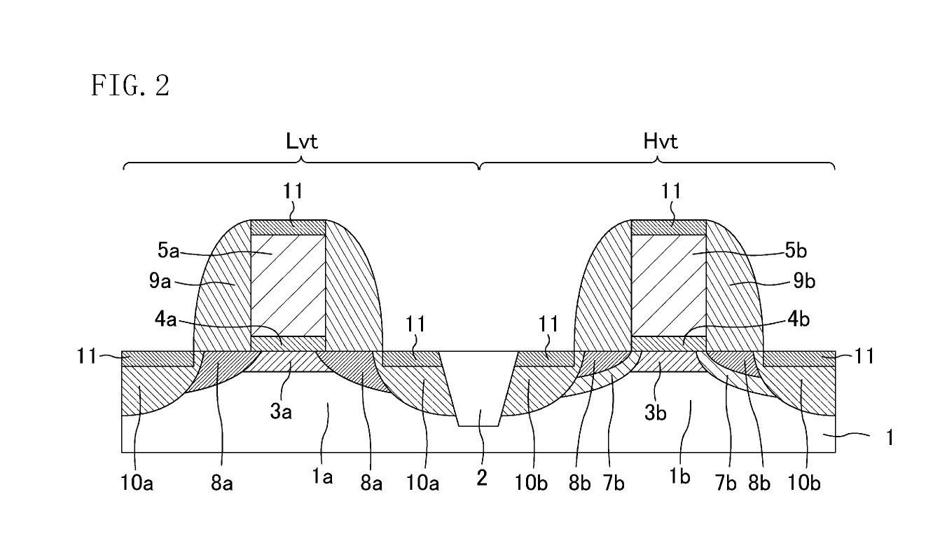

The structure of the semiconductor device according to this embodiment will be briefly described with reference to FIG. 2. FIG. 2 is a cross-sectional view illustrating the semiconductor device according to this embodiment. The reference characters “Lvt” and “Hvt” in FIG. 2 are as described above.

In the semiconductor device according to this embodiment, the isolation region 2 is selectively formed in the upper portion of the semiconductor substrate 1. As a result, the first active region 1a surrounded by the isolation region 2 and formed of the semiconductor substrate 1 is provided in the formation region Lvt of the first n-type MIS transistor. The second active region 1b surrounded by the isolation region 2 and formed of the semiconductor substrate 1 is provided in the formation region Hvt of the second n-type MIS transistor. The first n-type MIS transistor is formed on the first active region 1a, and the second n-type MIS transistor is formed on the second active region 1b. The threshold voltage of the second n-type MIS transistor is higher than the threshold voltage of the first n-type MIS transistor. For example, when the threshold voltage of the first n-type MIS transistor is 0.2 V, the threshold voltage of the second n-type MIS transistor is 0.3V.

In the first n-type MIS transistor, the first p-type channel region 3a is formed in the first active region 1a. The first gate insulating film 4a and the first gate electrode 5a are sequentially formed on the first p-type channel region 3a. The first sidewalls 9a are formed on the side surfaces of the first gate electrode 5a. In the first active region 1a, the first n-type extension region 8a is formed below the side of the first gate electrode 5a. In the first active region 1a, the first p-type pocket region (not shown) is formed below the first n-type extension region 8a. In the first active region 1a, the first n-type source/drain regions 10a are formed below the sides of the first sidewalls 9a. The silicide films 11 are formed in the upper portions of the first n-type source/drain regions 10a, and in the upper portion of the first gate electrode 5a.

In the second n-type MIS transistor, the second p-type channel region 3b is formed in the second active region 1b. The second gate insulating film 4b and the second gate electrode 5b are sequentially formed on the second p-type channel region 3b. The second sidewalls 9b are formed on the side surfaces of the second gate electrode 5b. In the second active region 1b, the second n-type extension region 8b is formed below the side of the second gate electrode 5b. In the second active region 1b, the second p-type pocket region (not shown) is formed below the second n-type extension region 8b. In the second active region 1b, the second n-type source/drain regions 10b are formed below the sides of the second sidewalls 9b. The silicide films 11 are formed in the upper portions of the second n-type source/drain regions 10b, and in the upper portion of the second gate electrode 5b. The concentration of the p-type impurities in the second p-type channel region 3b is substantially equal to the concentration of the p-type impurities in the first p-type channel region 3a. The concentration of the p-type impurities of the second p-type pocket region is substantially equal to the concentration of the p-type impurities of the first p-type pocket region. The concentration of the n-type impurities in the second n-type source/drain regions 10b is substantially equal to the concentration of the n-type impurities in the first n-type source/drain regions 10a.

In the second n-type MIS transistor, the implant region 7b of the impurities for shallower junction is formed at a lower position than the second n-type extension region 8b in the second active region 1b. The impurities for shallower junction are implanted into the implant region 7b of the impurities for shallower junction. The impurities for shallower junction prevent the junction depth of the second n-type extension region 8b from being deeper than the junction depth of the first n-type extension region 8a. The impurities for shallower junction reduce diffusion of the n-type impurities existing in the second n-type extension implant region 8B in the step of diffusing the conductive impurities in the manufacturing process of the semiconductor device. The impurities for shallower junction are contained not only in the implant region 7b of the impurities for shallower junction but also in the second n-type extension region 8b.

As such, the second n-type MIS transistor includes the implant region 7b of the impurities for shallower junction at a lower position than the second n-type extension region 8b. Thus, in the semiconductor device according to this embodiment, the junction depth of the second n-type extension region 8b is shallower than the junction depth of the first n-type extension region 8a. As a result, the effective channel length of the second n-type MIS transistor is greater than the effective channel length of the first n-type MIS transistor, thereby reducing the short channel effect in the second n-type MIS transistor as compared to the first n-type MIS transistor. Therefore, as described above, the threshold voltage of the second n-type MIS transistor can be higher than the threshold voltage of the first n-type MIS transistor.

In the semiconductor device according to this embodiment, the concentration of the p-type impurities in the first p-type channel region 3a is substantially equal to the concentration of the p-type impurities in the second p-type channel region 3b. The concentration of the p-type impurities in the first p-type pocket region is substantially equal to the concentration of the p-type impurities in the second p-type pocket region. As a result, reduction in the carrier mobility in the second p-type channel region 3b can be mitigated. In the semiconductor device according to this embodiment, the concentration of the n-type impurities in the first n-type source/drain regions 10a is substantially equal to the concentration of the n-type impurities in the second n-type source/drain regions 10b. Reduction in the driving force of the second n-type MIS transistor due to parasitic resistance can be prevented.

As described above, in the semiconductor device according to this embodiment, the threshold voltage of the second n-type MIS transistor can be higher than the threshold voltage of the first n-type MIS transistor without reducing the driving force of the second n-type MIS transistor.

Note that the device according to this embodiment may have the following structure.

When the implant region 7b of the impurities for shallower junction is formed, the impurities for shallower junction are implanted into a deeper position of the second active region 1b than the second n-type extension implant region 8B only. In this case, as well, in the manufactured semiconductor device, the junction depth of the second n-type extension region 8b can be shallower than the junction depth of the first n-type extension region 8a. Therefore, the threshold voltage of the second n-type MIS transistor can be higher than the threshold voltage of the first n-type MIS transistor.

In this embodiment, the first and second n-type extension implant regions, and the first and second p-type pocket implant regions are formed after implanting the impurities for shallower junction. However, the impurities for shallower junction may be implanted into the semiconductor substrate before diffusing the conductive impurities, and before forming the first and second sidewalls in the step shown in FIG. 1C. For example, the impurities for shallower junction may be implanted into the semiconductor substrate after forming the first and second n-type extension implant regions, and the first and second p-type pocket implant regions, and before forming the first and second sidewalls. The impurities for shallower junction may be implanted into the semiconductor substrate after forming the first and second n-type extension implant regions, and before forming the first and second p-type pocket implant regions.

### Second Embodiment

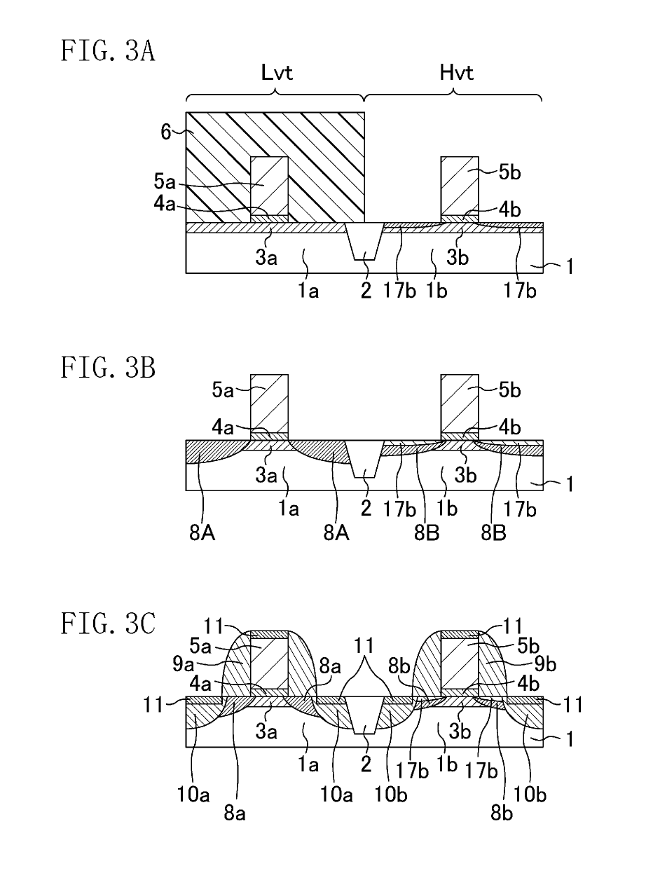

In a second embodiment, as in the above first embodiment, a region implanted with impurities for shallower junction exists in a portion of a second active region, which is located below a side of a second gate electrode. The impurities for shallower junction in this embodiment reduce implantation of conductive impurities into a deep position of the active region in the step of implanting the conductive impurities forming an extension region in a manufacturing process of a semiconductor device. A manufacturing method of a semiconductor device according to this embodiment will be described below with reference to FIGS. 3A-3C focusing on differences from the manufacturing method of the semiconductor device according to the first embodiment. FIGS. 3A-3C are cross-sectional views illustrating the manufacturing method of the semiconductor device according to this embodiment in order of steps. Note that the reference characters “Lvt” and “Hvt” in the figures are as described above in the first embodiment.

First, in accordance with the step shown in FIG. 1A in the first embodiment, the isolation region 2, the first p-type channel region 3a, and the second p-type channel region 3b are formed in the upper portion of the semiconductor substrate 1. The gate insulating film 4 and the polysilicon film 5 are formed on the entire upper surface of the semiconductor substrate 1.

Then, in accordance with the step shown in FIG. 1B in the first embodiment, the gate insulating film 4 and the polysilicon film 5 are patterned. As a result, the first gate insulating film 4a and the first gate electrode 5a are sequentially formed on the first p-type channel region 3a, and the second gate insulating film 4b and the second gate electrode 5b are sequentially formed on the second p-type channel region 3b (step (b)).

Next, in the step shown in FIG. 3A, the upper surface of the first active region 1a and the upper surface of the portion of the isolation region 2 around the first active region 1a are covered with the resist mask 6. The impurities for shallower junction are implanted using the resist mask 6 and the second gate electrode 5b as a mask. As a result, an implant region 17b of the impurities for shallower junction is formed in the second active region 1b below the side of the second gate electrode 5b (step (c)). After that, the resist mask 6 is removed.

The impurities for shallower junction preferably have no conductivity type, and may be, for example, at least one of C, N, F, Ar, Ge, or Si. In this embodiment, the impurities for shallower junction are preferably at least one of Ar, Ge, or Si. When Si is used as the impurities for shallower junction, the silicon concentration in the implant region 17b of the impurities for shallower junction is higher than the silicon concentration in the semiconductor substrate 1 except for the implant region 17b of the impurities for shallower junction. When Ge is selected as the impurities for shallower junction, the implant energy may be, for example, 5 keV, and the implant dose may be, for example, 1×10¹⁵ cm⁻².

Then, in the step shown in FIG. 3B, n-type impurities are implanted into the first active region 1a using the first gate electrode 5a as a mask, while n-type impurities are implanted into the second active region 1b using the second gate electrode 5b as a mask. The implantation conditions are as described above in the first embodiment. As a result, the first n-type extension implant region 8A is formed in the first active region 1a below the side of the first gate electrode 5a (step (d)). Also, the second n-type extension implant region 8B is formed in the second active region 1b below the side of the second gate electrode 5b (step (d)).

At this time, the implant region 17b of the impurities for shallower junction is formed in the second active region 1b below the side of the second gate electrode 5b. The impurities for shallower junction reduce implantation of the n-type impurities into a deep position of the second active region 1b in this step. Therefore, as shown in FIG. 3B, the implant depth of the second n-type extension implant region 8B is shallower than the implant depth of the first n-type extension implant region 8A.

When a relatively heavy element (at least one of Ar, Ge, or Si) is selected as the impurities for shallower junction, the region implanted with the impurities for shallower junction (the implant region 17b of the impurities for shallower junction) tends to become amorphous. Thus, when n-type impurities are ion-implanted into the second active region 1b, in which the implant region 17b of the impurities for shallower junction is formed, the implantation of the n-type impurities to a deep position of the second active region 1b can be reduced. Therefore, in this embodiment, at least one of Ar, Ge, or Si is preferably selected as the impurities for shallower junction.

Since the second n-type extension implant region 8B contains not only the n-type impurities, but also the impurities for shallower junction, the second n-type extension region 8b contains not only the n-type impurities, but also the impurities for shallower junction.

After that, the semiconductor device according to this embodiment is manufactured in accordance with the method shown in the first embodiment. Specifically, the first p-type pocket implant region (not shown) is formed in the first active region 1a below the first n-type extension implant region 8A, and the second p-type pocket implant region is formed in the second active region 1b below the second n-type extension implant region 8B. Then, the first sidewalls 9a are formed on the side surfaces of the first gate electrode 5a, and second sidewalls 9b are formed on the side surfaces of the second gate electrode 5b. Next, the first n-type source/drain implant regions 10A are formed in the first active region 1a below the sides of the first sidewalls 9a, and the second n-type source/drain implant regions 10B are formed in the second active region 1b below the sides of the second sidewalls 9b. After that, spike RTA is performed to diffuse the conductive impurities. This electrically activates and diffuses the n-type impurities existing in the first and second n-type extension implant regions 8A and 8B, thereby forming the first and second n-type extension regions 8a and 8b. This also electrically activates and diffuses the p-type impurities existing in the first and second p-type pocket implant regions, thereby forming the first and second p-type pocket regions. This also electrically activates and diffuses the n-type impurities existing in the first and second n-type source/drain implant regions 10A and 10B, thereby forming the first and second n-type source/drain regions 10a and 10b (step (e)). At this time, in the step shown in FIG. 3B, the implant depth of the second n-type extension implant region 8B is shallower than the implant depth of the first n-type extension implant region 8A. Thus, the junction depth of the second n-type extension region 8b becomes shallower than the junction depth of the first n-type extension region 8a. After that, the silicide film 11 are formed in the upper portions of the first gate electrode 5a, the second gate electrode 5b, and the first n-type source/drain regions 10a and the second n-type source/drain regions 10b. As a result, the semiconductor device shown in FIG. 3C can be manufactured.

In the manufacturing method of the semiconductor device according to this embodiment, in the step shown in FIG. 3A, the implant region 17b of the impurities for shallower junction is formed in the second active region 1b. When the first and second n-type extension implant regions 8A and 8B are formed after that, the implant depth of the second n-type extension implant region 8B becomes shallower than the implant depth of the first n-type extension implant region 8A. Thus, in the manufactured semiconductor device, the junction depth of the second n-type extension region 8b is shallower than the junction depth of the first n-type extension region 8a. As a result, the manufacturing method of the semiconductor device according to this embodiment provides substantially same advantages as the manufacturing method of the semiconductor device according to the first embodiment.

Note that, in this embodiment, when the impurities for shallower junction are implanted into the second active region after forming the second n-type extension implant region, it is difficult to make the depth of the second n-type extension implant region shallower than the depth of the first n-type extension implant region. Therefore, in this embodiment, the implant region 17b of the impurities for shallower junction is preferably formed before forming the second n-type extension implant region 8B.

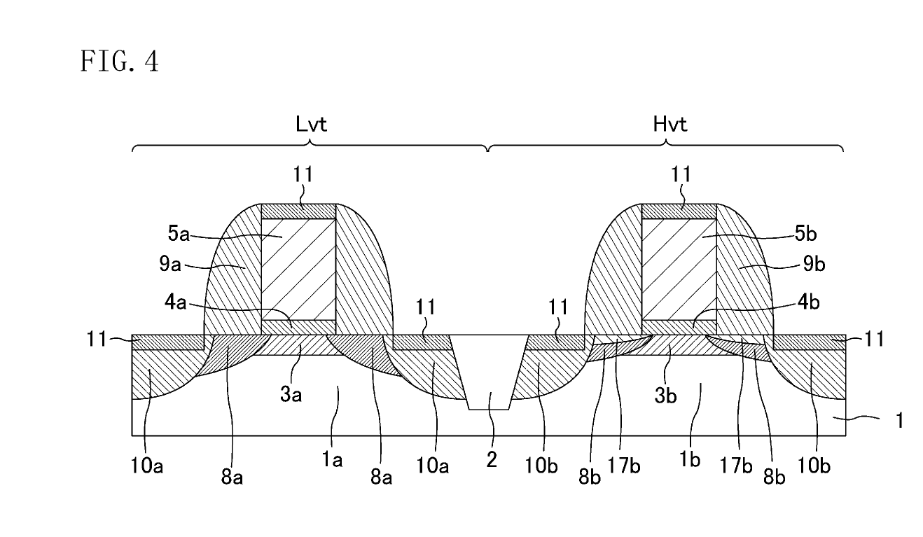

The structure of the semiconductor device according to this embodiment will be briefly described with reference to FIG. 4. FIG. 4 is a cross-sectional view illustrating the semiconductor device according to this embodiment.

Similar to the semiconductor device according to the first embodiment, the semiconductor device according to this embodiment includes a first n-type MIS transistor and a second n-type MIS transistor. The threshold voltage of the second n-type MIS transistor is higher than the threshold voltage of the first n-type MIS transistor. Specifically, when the threshold voltage of the first n-type MIS transistor is about 0.2 V, the threshold voltage of the second n-type MIS transistor is about 0.3 V. The first n-type MIS transistor in this embodiment has the same structure as the first n-type MIS transistor in the first embodiment. Therefore, explanation of the structure of the first n-type MIS transistor will be omitted in this embodiment.

In the second n-type MIS transistor, the second gate insulating film 4b and the second gate electrode 5b are sequentially formed on the second p-type channel region 3b, and the second sidewalls 9b are formed on the side surfaces of the second gate electrode 5b. The second n-type extension region 8b is formed in the second active region 1b below the side of the second gate electrode 5b. The second n-type source/drain regions 10b are formed in the second active region 1b below the sides of the second sidewalls 9b. The silicide films 11 are formed in the upper portion of the second gate electrode 5b, and in the upper portions of the second n-type source/drain regions 10b. The implant region 17b of the impurities for shallower junction is formed at a higher position than the second n-type extension region 8b in the second active region 1b. The impurities for shallower junction are implanted into the implant region 17b of the impurities for shallower junction. The impurities for shallower junction reduce implantation of the n-type impurities into a deep position of the second active region 1b, when the second n-type extension implant region 8B is formed. Note that, the impurities for shallower junction are contained not only in the implant region 17b of the impurities for shallower junction, but also in the second n-type extension region 8b.

As such, the second n-type MIS transistor includes the implant region 17b of the impurities for shallower junction. In the step of forming the first and second n-type extension implant regions 8A and 8B in the manufacturing process of the semiconductor device, the implant depth of the n-type impurities in the second active region 1b is shallower than the implant depth of the n-type impurities in the first active region 1a. Thus, in the semiconductor device according to this embodiment, the junction depth of the second n-type extension region 8b is shallower than the junction depth of the first n-type extension region 8a. Therefore, as described above in the first embodiment, the threshold voltage of the second n-type MIS transistor can be higher than the threshold voltage of the first n-type MIS transistor.

As in the semiconductor device according to the first embodiment, the concentration of the p-type impurities in the second p-type channel region 3b is substantially equal to the concentration of the p-type impurities in the first p-type channel region 3a in the semiconductor device according to this embodiment. The concentration of the p-type impurities of the second p-type pocket region is substantially equal to the concentration of the p-type impurities of the first p-type pocket region. The concentration of the n-type impurities in the second n-type source/drain regions 10b is substantially equal to the concentration of the n-type impurities in the first n-type source/drain regions 10a. As a result, the threshold voltage of the second n-type MIS transistor can be higher than the threshold voltage of the first n-type MIS transistor without reducing the driving force of the second n-type MIS transistor.

Note that the device according to this embodiment may have the following structure.

The semiconductor device of this embodiment preferably includes the structure of the first embodiment. Specifically, the semiconductor device according to this embodiment preferably includes not only the implant region 17b of the impurities for shallower junction in this embodiment, but also the implant region 7b of the impurities for shallower junction in the first embodiment. In the manufacturing method of the semiconductor device according to this embodiment, not only the impurities (preferably Ge, Ar, or Si) for shallower junction for mitigating an increase in the implant depth are implanted into the second active region before forming the first and second n-type extension regions, but also impurities (preferably C, F, or N) for shallower junction for reducing diffusion caused by heat treatment (spike RTA) may be implanted into the second active region before forming the sidewalls. At this time, the former impurities for shallower junction are preferably implanted into a shallower position than the second n-type extension implant region. The latter impurities for shallower junction are preferably implanted into a deeper position than the second n-type extension implant region. This further makes the junction depth of the second n-type extension region shallower than the junction depth of the first n-type extension region, as compared to this embodiment. Therefore, the threshold voltage of the second n-type MIS transistor can be further higher than the threshold voltage of the first n-type MIS transistor.

### Other Embodiments

The devices of the first and the second embodiments may have the following structure.

When the region implanted with the impurities for shallower junction is formed, the impurities for shallower junction may be implanted into the first active region, as well. In this case, the dose of the impurities for shallower junction implanted into the first active region may be about ½ of the dose of the impurities for shallower junction implanted into the second active region. In this case, as well, the threshold voltage of the second n-type MIS transistor can be higher than the threshold voltage of the first n-type MIS transistor. Recently, a gate length tends to be shorter. With reduction in the gate length, it becomes difficult to implant the impurities for shallower junction into the second active region only. As such, when it is difficult to implant the impurities for shallower junction into the second active region only, the impurities for shallower junction may also be implanted into the first active region, and the dose of the impurities for shallower junction implanted into the first active region may be about ½ of the dose of the impurities for shallower junction implanted into the second active region.

The junction depth of the first p-type channel region may be deeper than the junction depths of the first n-type source/drain regions. The junction depth of the second p-type channel region may be deeper than the junction depths of the second n-type source/drain regions. In this case, as well, a leakage current from the second p-type pocket region to the second n-type source/drain regions can be reduced. A leakage current from the second n-type source/drain regions to the semiconductor substrate can be also reduced.

A first offset spacer may be provided between the first gate electrode and each of the first sidewalls, and a second offset spacer may be provided between the second gate electrode and each of the second sidewalls. In the manufacturing method of such a semiconductor device, the first offset spacer may be formed on the side surface of the first gate electrode, and the second offset spacer may be formed on the side surface of the second gate electrode after forming the region implanted with the impurities for shallower junction, and before forming the first and second n-type extension implant regions (between the step shown in FIG. 1B and the step shown in FIG. 1C in the first embodiment, and between the step shown in FIG. 3A and the step shown in FIG. 3B in the second embodiment).

The number of the MIS transistors included in the semiconductor device may be 3 or more.

The MIS transistors may have p-type conductivity. In this case, the channel regions and the pocket regions have n-type conductivity, and the extension regions and the source/drain regions have p-type conductivity type. The impurities for shallower junction may be the materials shown in the first and second embodiments.

The first and second extension implant regions may be formed after forming the first and second pocket implant regions.

As long as the carrier mobility in the second channel region does not decrease, the concentration of the conductive impurities in the second channel region may be higher than the concentration of the conductive impurities in the first channel region, and the concentration of the conductive impurities in the second pocket region may be higher than the concentration of the conductive impurities in the first pocket region. As long as the resistances of the second source/drain regions do not increase, the concentration of the conductive impurities in the second source/drain regions may be lower than the concentration of the conductive impurities in the first source/drain regions.

Each of the gate insulating films may be a high-dielectric constant film (a film having higher dielectric constant than a silicon nitride film) and each of the gate electrodes may be a multilayer of a metal film (e.g., a TiN film) and a polysilicon film. This configuration tends to make the work function of the first and second MIS transistors close to the midgap as compared to the case where the gate insulating films are silicon oxide films and the gate electrodes are polysilicon electrodes. This increases not only the threshold voltage of the second MIS transistor but also the threshold voltage of the first MIS transistor. In this case, no impurity for shallower junction is preferably implanted into the first active region. When the impurities for shallower junction are implanted into the first active region, the dose of the impurities for shallower junction implanted into the first active region is preferably reduced as compared to the case where the gate insulating films are silicon oxide films and the gate electrodes are polysilicon electrodes.

Note that, as described above, the present disclosure is useful for a semiconductor device including MIS transistors having a same conductivity type and different threshold voltages, and the manufacturing method of the device.

What is claimed is:

1. A semiconductor device comprising:
a first transistor having a first conductivity type; and
a second transistor having the first conductivity type and having a higher threshold voltage than the first transistor, wherein
the first transistor includes
a first channel region having a second conductivity type and formed in a first active region of a semiconductor substrate,
a first gate insulating film provided on the first channel region of the first active region,
a first gate electrode provided on the first gate insulating film, and
a first extension region having the first conductivity type and formed in a part of the first active region which is located below a side of the first gate electrode,
the second transistor includes
a second channel region having the second conductivity type and formed in a second active region of the semiconductor substrate,
a second gate insulating film provided on the second channel region of the second active region,
a second gate electrode provided on the second gate insulating film, and
a second extension region having the first conductivity type and formed in a part of the second active region which is located below a side of the second gate electrode,
the second extension region contains impurities for shallower junction, and
a junction depth of the second extension region is shallower than a junction depth of the first extension region.

2. The semiconductor device of claim 1, wherein
the first extension region does not contain the impurities for shallower junction.

3. The semiconductor device of claim 1, wherein
the first extension region contains the impurities for shallower junction, and
a concentration of the impurities for shallower junction in the first extension region is lower than a concentration of the impurities for shallower junction in the second extension region.

4. The semiconductor device of claim 1, wherein
the impurities for shallower junction have no conductivity.

5. The semiconductor device of claim 1, wherein
a junction depth of a region implanted with the impurities for shallower junction is deeper than a junction depth of the second extension region.

6. The semiconductor device of claim 1, wherein
a junction depth of a region implanted with the impurities for shallower junction is shallower than a junction depth of the second extension region.

7. The semiconductor device of claim 1, wherein
the impurities for shallower junction are at least one of C, N, F, Ar, or Ge.

8. The semiconductor device of claim 1, wherein
the semiconductor substrate is made of silicon, and
a silicon concentration in a region implanted with the impurities for shallower junction is higher than a silicon concentration in the semiconductor substrate except for the region implanted with the impurities.

9. The semiconductor device of claim 1, wherein
the first channel region has an impurity concentration substantially equal to an impurity concentration of the second channel region.

10. The semiconductor device of claim 5, wherein
the impurities for shallower junction are at least one of C, N, or F.

11. The semiconductor device of claim 6, wherein
the impurities for shallower junction are at least one of Ar or Ge.

12. The semiconductor device of claim 1, wherein
an effective channel length of the second transistor is greater than an effective channel length of the first transistor.

13. The semiconductor device of claim 1, further comprising:
a first pocket region having the second conductivity type and formed in the first active region below a side of the first gate electrode and at a lower position than the first extension region; and
a second pocket region having the second conductivity type and formed in the second active region below a side of the second gate electrode and at a lower position than the second extension region, wherein
a concentration of impurities having the second conductivity type in the second pocket region is substantially equal to a concentration of impurities having the second conductivity type in the first pocket region.

14. The semiconductor device of claim 1, further comprising:
first sidewalls formed on side surfaces of the first gate electrode,
second sidewalls formed on side surfaces of the second gate electrode;
first source/drain regions having the first conductivity type and formed in the first active region below outer side surfaces of the first sidewalls; and
second source/drain regions having the first conductivity type and formed in the second active region below outer side surfaces of the second sidewalls, wherein
a concentration of impurities having the first conductivity type in the second source/drain regions is substantially equal to a concentration of impurities having the first conductivity type in the first source/drain regions.

15. The semiconductor device of claim 14, further comprising:
first silicide films formed in upper portions of the first source/drain regions; and
second silicide films formed in upper portions of the second source/drain regions.

16. The semiconductor device of claim 1, wherein
each of the first gate insulating film and the second gate insulating film includes a film having a higher dielectric constant than a silicon nitride film.

17. The semiconductor device of claim 1, wherein
each of the first gate electrode and the second gate electrode is formed of a multilayer of a metal film and a polysilicon film.
